(19) United States
(12) Patent Application Publication
(10) Pub. No.: US 2013/0186674 A1
(43) Pub. Date: Jul. 25, 2013

(54) MULTI-LAYER PRINTED CIRCUIT BOARD (PCB)

(71) Applicants: Peking University Founder Group Co., Ltd., Beijing (CN); Chongqing founder Hi-Tech Electronic Inc., Chongqing (CN); Zhuhai Founder PCB Development Co., Ltd., Zhuhai (CN)

(72) Inventor: Sheng YI, Beijing (CN)

(73) Assignees: Peking University Founder Group Co., Ltd., Beijing (CN); Zhuhai Founder PCB Development Co., Ltd., Zhuhai (CN); Chongqing founder Hi-Tech Electronic Inc., Chongqing (CN)

(21) Appl. No.: 13/717,431

(22) Filed: Dec. 17, 2012

(30) Foreign Application Priority Data
Dec. 15, 2011 (CN) 201120526841.8

(51) Int. Cl. H05K 3/46

(52) U.S. Cl. CPC H05K 3/46
USPC 174/251; 216/17

(57) ABSTRACT

Embodiments of the present disclosure relate to the field of printed circuit boards and particularly to a multi-layer printed circuit board. The multi-layer printed circuit board includes at least two inner-layer circuit boards, each of which has a non-circuit pattern area including a welding area. Each welding area has at least one welding hole. Further, at least one prepreg is used to fill between two adjacent inner-layer circuit boards and is melted to fill into the welding hole in a welding process. In the multi-layer printed circuit board according to the embodiments of the disclosure, a welding area is arranged in a non-circuit pattern area, and one or more welding holes are arranged in the welding area so that a prepreg between two inner-layer circuit boards can be melted filling into the welding hole(s) in a welding process, thus enhancing effectively an adhesive force binding the inner-layer circuit boards.

### FIELD

The present disclosure relates to printed circuit boards and particularly to a multi-layer printed circuit boards.

### BACKGROUND

At present a multi-layer Printed Circuit Board (PCB) is fabricated by firstly blackening/browning a developed and etched inner-layer circuit board, then adding prepregs between inner-layer circuit boards, and then thermally pressing inner-layer circuit boards with an outer-layer copper foil. Subsequently, drilling, through hole plating, developing and etching to form outer-layer circuits, etc., are performed, and then ink printing, surface processing, shaping, testing and other procedures are performed to thereby complete the multi-layer board.

A process of laminating a multi-layer board may include processing steps of bonding, pre-stacking, stacking, thermal pressing, cold pressing, post-processing, etc. Particularly, a bonding step may refer to stacking and aligning all the inner-layer circuit boards so as to prevent a failed product due to layer displacement. Three bonding processes are common: riveting, welding and PIN-Lam, where the welding process is favored by large, medium and small enterprises due to a simple flow, a modest investment in equipment, a high production capacity and highly precise inter-layer alignment.

However, in a traditional welding process, when the welded inner-layer circuit boards are thick and the thick sub-boards are laminated many times, inner-layer circuit boards may easily slide relatively to each other during thermal pressing at high temperature and pressure. Consequently, the inner-layer circuit boards may be displaced from each other, thus resulting in a failure of the product. This is because the inner-layer circuit boards may have a poor thermal conductivity coefficient which may cause a poor welding.

### SUMMARY

An embodiment of the present disclosure provides a multi-layer printed circuit board which can increase adhesion between inner-layer circuit boards.

A multi-layer printed circuit board according to an embodiment of the present disclosure may include: at least two inner-layer circuit boards, each of which includes a non-circuit pattern area including a welding area in which there is at least one welding hole; and at least one prepreg filled between two adjacent inner-layer circuit boards and melted to fill into the welding hole in a welding process.

In some preferred embodiments, the welding hole may be a through hole formed continuously through two adjacent inner-layer circuit boards.

In some preferred embodiments, the welding area may be consistent in location among the inner-layer circuit boards.

In some preferred embodiments, the welding holes in the welding area of the inner-layer circuit boards may be consistent in number and correspond in location to each other.

In some preferred embodiments, a diameter of the welding hole may be 0.5 to 1 mm.

In some preferred embodiments, the welding hole may be a metalized welding hole or a non-metalized welding hole.

In some preferred embodiments, when there is more than one welding hole, the welding holes may be arranged in a matrix form.

In some preferred embodiments, the spacing between two adjacent welding holes may be 0.5 to 1.5 mm.

In a multi-layer printed circuit board according to the embodiments of the disclosure, a welding area may be arranged in a non-circuit pattern area, and a plurality of welding holes may be arranged in the welding area so that the prepreg between two inner-layer circuit boards is melted to fill into the welding holes in a welding process, thus increasing adhesiveness between the inner-layer circuit boards.

### BRIEF DESCRIPTION OF THE DRAWINGS

FIG. 1 is a schematic structural diagram of a multi-layer printed circuit board according to an embodiment of the present disclosure;

FIG. 2 is a schematic diagram of the locations of welding holes in an inner-layer circuit board according to an embodiment of the present disclosure;

FIG. 3 is a flow chart illustrating an exemplary process of fabricating an inner-layer circuit board according to an embodiment of the present disclosure; and

FIG. 4a to FIG. 4c are schematic structural diagrams of fabricating a multi-layer printed circuit board according to the embodiment of the present disclosure.

### DETAILED DESCRIPTION OF THE EMBODIMENTS

Embodiments of the present disclosure will be described in further detail below with reference to the drawings.

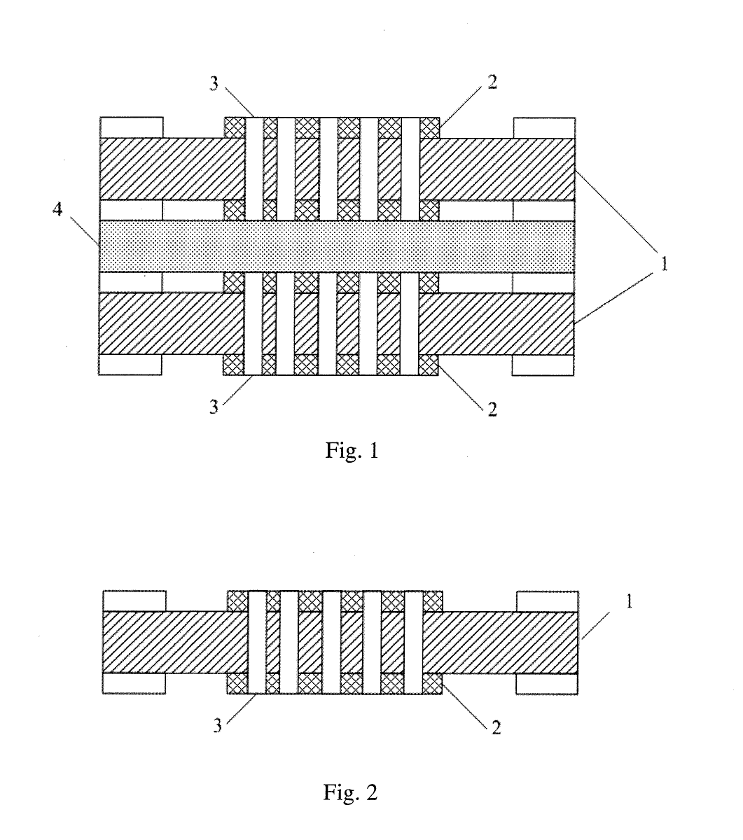

An embodiment of the present disclosure provides a multi-layer printed circuit board as illustrated in FIG. 1, which particularly includes: at least two inner-layer circuit boards 1, each of which includes a non-circuit pattern area including a welding area 2 in which there is at least one welding hole 3; and at least one prepreg 4 filled between two adjacent inner-layer circuit boards 1 and melted to fill into the welding hole 3 in a welding process.

Specifically, a plurality of inner-layer circuit boards 1 are laminated into a multi-layer printed circuit board. A multi-layer printed circuit board may be fabricated by the processes of fabricating inner-layer circuit boards, Post-Etch (PE) punching, inner-layer Automated Optical Inspection (AOI), drilling, browning, welding and other steps.

Further, each inner-layer circuit board may be fabricated by the processes of inner-layer boards pre-processing, film application, exposure, development, etching, film removal and other steps to treat inner-layer circuit board 1. An inner-layer circuit board 1 may be exposed, developed and etched to form a welding area according to a design pattern. Welding area 2 of each inner-layer circuit board 1 may be arranged to be consistent in location among the respective inner-layer circuit boards 1.

Then a positioning hole may be punched on each inner-layer circuit board 1 using upper and lower dies of a punching machine. The positioning hole is intended to position the respective inner-layer circuit board 1 in a subsequent welding process so that the plurality of inner-layer circuit boards 1 may be aligned in place. Further, at least one welding hole 3 is formed in the welding area 2. A diameter of the welding hole 3 may be 0.5 to 1 mm, for example, about 0.5 mm (2 mils). When there is more than one welding hole, the welding holes can be arranged in a form of a matrix. A spacing between two adjacent welding holes may be 0.5 to 1.5 mm, for example, about 1 mm (i.e., 4 mils). A coverage area of the matrix of welding holes 3 may depend on a size of the welding area 2. The respective welding holes 3 may be arranged in a form of a matrix located within the welding area 2.

The welding hole 3 may be a metalized welding hole or a non-metalized welding hole. Often, a welding hole has no copper or other metal substance therein. However copper or other metal substances may be present in the welding hole 3 due to different structures of the respective inner-layer circuit boards 1.

As illustrated in FIG. 2, the welding hole 3 in the welding area 2 may be formed to penetrate through the inner-layer circuit board 1. If the welding hole 3 is not formed to penetrate through the inner-layer circuit board 1, then bubbles may easily occur in the welding hole 3 in a subsequent wedging process. The welding hole 3 formed to penetrate through the inner-layer circuit board 1 will not suffer from the problem of bubbles and thus a printed circuit board may have good applicability.

After the inner-layer circuit boards 1 are fabricated, the respective inner-layer circuit boards 1 may be stacked in sequence. A prepreg 4 is filled between the respective inner-layer circuit boards 1. Particularly, the welding holes 3 in the welding area 2 of the respective inner-layer circuit boards 1 are consistent in number and correspond in location to each other. Then the prepreg 4 in the welding area 2 is melted and bonded together with the inner-layer circuit boards 1 by high temperate and pressure of welding heads of a welding machine. Since there is at least one welding hole 3 in the welding area 2, the prepreg 4 can be melted at high temperate and flow into and fill the welding hole 3, thus enhancing a welding adhesive force and preventing layer displacement during the thermal pressing to ensure good alignment precision.

As can be understood from the foregoing descriptions, in a multi-layer printed circuit board according to embodiments of the disclosure, a welding area may be arranged in the non-circuit pattern area, and one or more welding holes may be arranged in the welding area so that a prepreg between two inner-layer circuit boards can be melted to fill into the welding hole(s) in a welding process, thus enhancing an adhesive force between the inner-layer circuit boards.

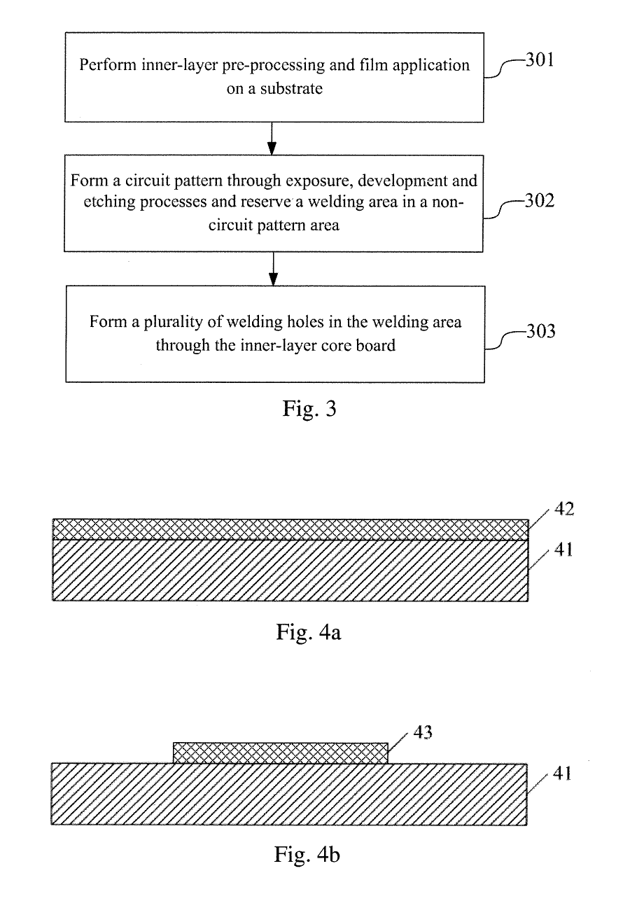

A multi-layer printed circuit board according to an embodiment of the disclosure will be described in detail below. As illustrated in FIG. 3, a process of fabricating each inner-layer circuit board in the multi-layer printed circuit board includes the following steps:

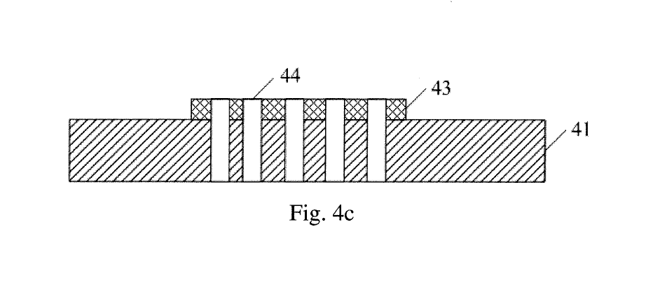

Step 301: A substrate is undergone an inner-layer pre-processing step and a thin film is applied to the substrate. As illustrated in FIG. 4a, an inner-layer pre-processing is performed respectively on top and bottom surfaces of a substrate 41, and a thin film 42 is applied to substrate 41.

Step 302: A process is performed to form a circuit pattern through exposure, development and etching processes and to reserve a welding area in a non-circuit pattern area. Specifically, as illustrated in FIG. 4b, a welding area 43 is formed in the non-circuit pattern area through exposure, development and etching processes. The welding area 43 is located in the non-circuit pattern area and thus will not interfere with any circuit of the current inner-layer circuit board.

Step 303: A process is performed to form a plurality of welding holes in the welding area to penetrate through the inner-layer circuit board. Specifically, as illustrated in FIG. 4c, a plurality of welding holes 44 are drilled in the welding area 43 using a digitally controlled drilling machine, where the plurality of welding holes 44 may be arranged in a form of a matrix. A diameter of the welding hole 44 is about 0.5 mm, and the spacing between two adjacent welding holes 44 is about 1 mm.

After the inner-layer circuit boards are fabricated, a predetermined number of inner-layer circuit boards are stacked together, and a prepreg is filled between two adjacent inner-layer circuit boards. In a subsequent welding process, the prepreg starts to be melted in a high temperature into a liquid gel that adheres two inner-layer circuit boards. The liquid gel then flows into the welding holes, thus further enhancing an inter-layer adhesive force and preventing layer displacement.

As can be understood from the foregoing descriptions, in a multi-layer printed circuit board according to the embodiment of the disclosure, a welding area may be arranged in a non-circuit pattern area, and a plurality of welding holes may be arranged in the welding area so that a prepreg between two inner-layer circuit boards may be melted to fill into the welding holes in a welding process, thus enhancing an adhesive force between the inner-layer circuit boards.

It would be obvious for those skilled in the art to make various modifications and variations to the disclosure without departing from the spirit and scope of the disclosure. Thus the disclosure is intended to encompass these modifications and variations thereto within the scope of the claims of the disclosure and their equivalents.

1. A multi-layer printed circuit board, comprising:
at least two inner-layer circuit boards, each of the two inner-layer circuit boards has a non-circuit pattern area including a welding area, the welding area having at least one welding hole; and
at least one prepreg filled between two adjacent inner-layer circuit boards and into the welding hole.

2. The multi-layer printed circuit board according to claim 1, wherein the welding hole of one inner-layer circuit board is formed to penetrate through the two adjacent inner-layer circuit boards.

3. The multi-layer printed circuit board according to claim 1, wherein the numbers of the welding holes in the welding area of the adjacent two inner-layer circuit boards are the same and locations of the welding holes in the welding area of one inner-layer circuit board correspond to the locations of the welding holes of the other inner-layer circuit board.

4. The multi-layer printed circuit board according to claim 1, wherein a diameter of the welding hole is between 0.5 to 1 mm.

5. The multi-layer printed circuit board according to claim 1, wherein a welding hole is a metalized welding hole or a non-metalized welding hole.

6. The multi-layer printed circuit board according to claim 1, wherein when one inner-layer circuit board has more than one welding holes, the welding holes are arranged in a form of a matrix.

7. The multi-layer printed circuit board according to claim 6, wherein a spacing between two adjacent welding holes is between 0.5 to 1.5 mm.

8. A method to fabricate a multi-layer printed circuit board, comprising:
applying a thin film on a surface of a substrate;
forming a circuit pattern area and a non-circuit pattern area in the substrate by exposure, development, and etching processes, wherein the thin film is removed from the circuit pattern area and remains on the non-circuit pattern area;
forming a through hole at the non-circuit pattern area, the through hole penetrating through the thin film and the substrate; and
filling the through hole at the non-circuit pattern area with a prepreg.

9. The method according to claim 8, wherein the through hole is formed by drilling through the thin film and the substrate.
